(19) United States
(12) Patent Application Publication
(10) Pub. No.: US 2011/0114295 A1
(43) Pub. Date: May 19, 2011

(54) HEAT DISSIPATION MODULE

(75) Inventor: HUNG-NIEN CHIU, Tu-Cheng (TW)

(73) Assignee: FOXCONN TECHNOLOGY CO., LTD., Tu-Cheng (TW)

(21) Appl. No.: 12/637,758

(22) Filed: Dec. 15, 2009

(30) Foreign Application Priority Data
Nov. 17, 2009 (CN) 200910309852.8

(51) Int. Cl. H01L 23/40; F28D 15/04; H01L 23/427

(52) U.S. Cl. 165/104.26; 165/104.33; 165/185

(57) ABSTRACT

An exemplary heat dissipation module includes a base defining four through apertures and four fasteners. The base forms four sleeves surrounding the four through apertures, respectively. The sleeve has a through slot defined therein along an axial direction thereof thereby separating the sleeve into two clamping portions spaced from each other. The fastener is pushed downwardly into the through aperture, an annular flange of the fastener is driven to enter the small hole such that the two clamping portions elastically expand outwardly away from each other. After the annular flange passed through the small hole, the clamping portions rebound back to their original states and the annular flange abuts against a bottom of the sleeve, with the coil spring is located between the head portion of the fastener and the step of the sleeve.

### BACKGROUND

1. Technical Field

The present disclosure relates to heat dissipation modules, and particularly to a heat dissipation module suitable for use in a device such as a computer for dissipating heat of heat-generating electronic components of the computer.

2. Description of Related Art

With the continuing development of electronics technology, electronic packages such as CPUs (central processing units) are more powerful and liable to generate more heat than previously. When the electronic package is installed and in use in an electronic device, the generated heat requires immediate dissipation. A thermal module is usually mounted on the electronic package for dissipating the heat generated thereby. A plurality of mounting elements are needed for securing the thermal module onto the electronic package.

Typically, each mounting element includes a bolt. The bolt has a head, and defines an annular groove in an outer circumferential surface near a bottom end. A spring is disposed around a top end of the bolt, and a ring-like clipping member (such as a C-clip) is provided. The clipping member is made of a metal with good resiliency, and is capable of being snappingly engaged in the groove. In assembly of the thermal module, the bottom end of each of the bolts is extended through a corresponding through aperture defined in a base of the thermal module, and the corresponding clipping member is snapped into the groove of the bottom end of the bolt. Thus, the spring is biased between the head and the base of the thermal module, and the bolt is stopped from moving up away from the through aperture of the thermal module. Thereby, the bolts are pre-assembled onto the thermal module. The bolts are then screwed into screw apertures defined in a circuit board on which the electronic component is mounted, to assemble the thermal module onto the electronic component and the circuit board.

During the pre-assembling of the bolts and the clipping members to the thermal module, there is no mechanism provided which can reliably ensure that the clipping members are properly snapped into the grooves of the bolts. That is, the clipping members may not be firmly and fittingly snapped into the grooves. When this happens, the clipping members are liable to drop off from the bolts during transportation of the pre-assembled thermal module.

Therefore, a heat dissipation module is desired to overcome the above described shortcomings.

### BRIEF DESCRIPTION OF THE DRAWINGS

FIG. 1 is an exploded, isometric view of a heat dissipation module in accordance with an embodiment of the present disclosure.

FIG. 2 is an assembled view of the heat dissipation module of FIG. 1.

FIG. 3 is a cross-sectional view of a fastener of the heat dissipation module of FIG. 2, taken along line thereof.

### DETAILED DESCRIPTION

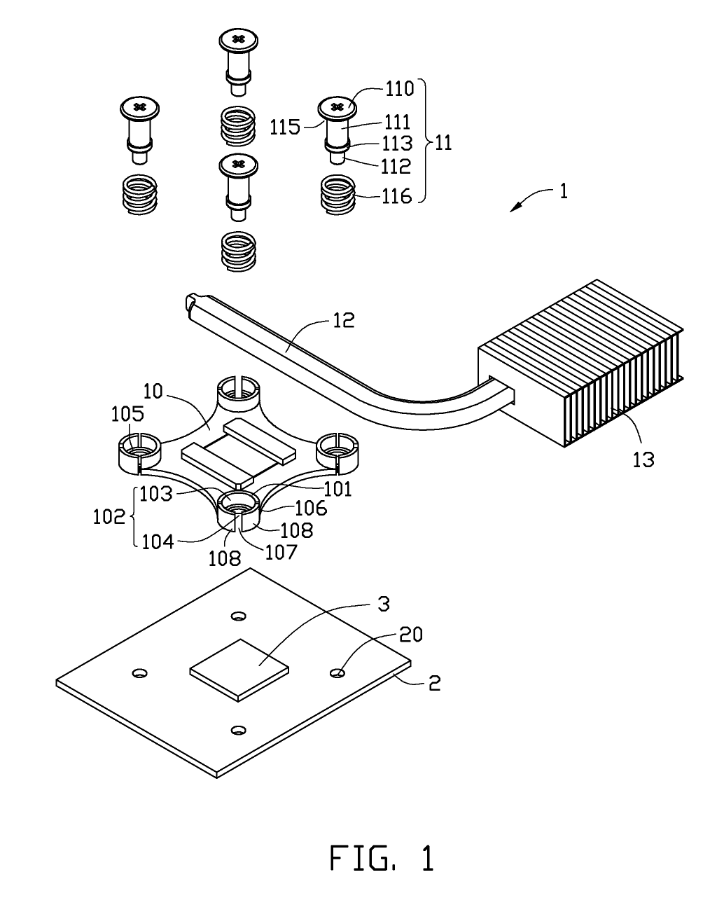

FIG. 1 shows a heat dissipation module 1 in accordance with an embodiment of the present disclosure. The heat dissipation module 1 includes a base 10, a plurality of fasteners 11, a heat pipe 12 and a fin assembly 13. One end of the heat pipe 12 is mounted on and thermally connected with the base 10. Another end of the heat pipe 12 extends through and is thermally connected with the fin assembly 13. An electronic component 3 such as a CPU is mounted on a circuit board 2. The base 10 is located on the circuit board 2 and the electronic component 3 is attached to a bottom surface of the base 10. The base 10 absorbs heat generated by the electronic component 3, and the heat pipe 12 transfers the heat from the base 10 to the fin assembly 13.

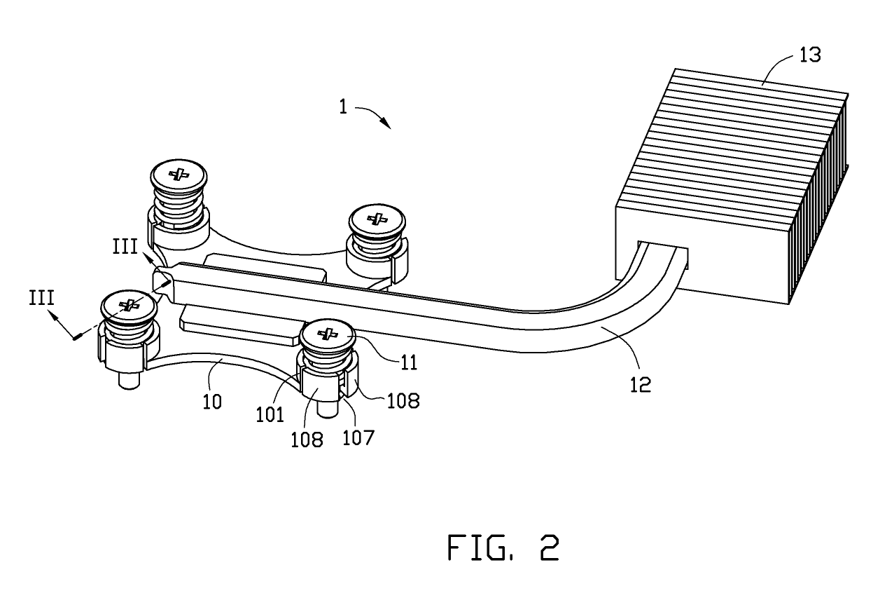

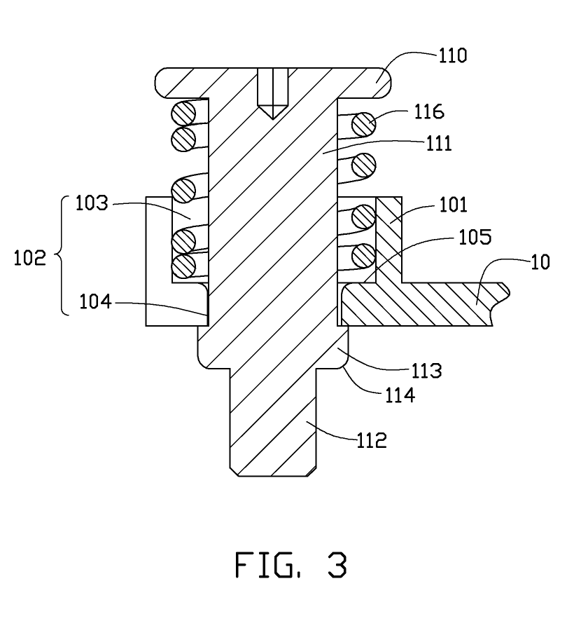

Referring also to FIGS. 2-3, each fastener 11 includes a column-shaped main portion 111, a head portion 110, a thread portion 112 and a coil spring 116. The head portion 110 is positioned at a top end of the main portion 111 and has a diameter larger than that of the main portion 111. The thread portion 112 is formed at a bottom end of the main portion 111 and has a diameter smaller than that of the main portion 111. An annular flange 113 extends radially and outwardly from an outer circumferential surface of the main portion 111 adjacent to the thread portion 112. Thereby, a generally annular groove 115 is defined around the main portion 111 between the head portion 110 and the annular flange 113. The annular flange 113 has an annular filleted surface 114 at a bottom thereof. The coil spring 116 is received in the annular groove 115 and surrounds the main portion 111 of the fastener 11.

The base 10 is substantially rectangular in profile, and forms four sleeves 101 at four corners thereof, respectively. Each sleeve 101 has a peripheral sidewall 106 extending up from the base 10, and defines a through aperture 102. The sidewall 106 surrounds the through aperture 102. The through aperture 102 includes a small hole 104 at a bottom of the sleeve 101 and a large hole 103 at a top of the sleeve 101. The large hole 103 has a diameter greater than that of the small hole 104. A step 105 is formed in the sidewall 106 where the large hole 103 communicates with the small hole 104. In the illustrated embodiment, the step 105 has an annular filleted surface at a top inner periphery thereof. The coil spring 116 has an outer diameter greater than the diameter of the small hole 104 of the through aperture 102. In the illustrated embodiment, the coil spring 116 has an inner diameter which is also greater than the diameter of the small hole 104 of the through aperture 102. The annular flange 113 has a diameter slightly greater than the diameter of the small hole 104 of the through aperture 102. A through slot 107 is defined in the sidewall 106 of the sleeve 101 parallel to an axis of the sleeve 101, thereby separating the sidewall 106 into two clamping portions 108 spaced from each other.

In assembly of the heat dissipation module 1, the following steps are performed for each fastener 11. The coil spring 116 is mounted to surround the main portion 111 of the fastener 11. The fastener 11 is placed in the corresponding through aperture 102 of the base 10 with the annular flange 113 resting on the step 105 of the through aperture 102. The head portion 110 of the fastener 11 is then pressed downwardly, and the annular filleted surface 114 drives the two clamping portions 108 to expand outwardly away from each other and thereby enlarge the small hole 104 of the through aperture 102. The annular filleted surface 114 guides the annular flange 113 to move into the small hole 104. When the annular flange 113 has completely passed through the small hole 104 of the through aperture 102, the clamping portions 108 resiliently rebound to their original states, and the small hole 104 thereby returns to its original dimension and state. The annular flange 113 abuts against a bottom of the sleeve 101, and the coil spring 116 is partly received in the large hole 103 and located between the head portion 110 of the fastener 11 and the step 105 of the sidewall 106. Thus, the fasteners 11 are pre-assembled to the base 10.

When assembling the base 10 to the electronic component 3, the thread portions 112 of the fasteners 11 are threadedly engaged in the screw holes 20 of the circuit board 2. Thus, the electronic component 3 is sandwiched between the circuit board 2 and the base 10, and intimately contacts the base 10. In the present embodiment, for each fastener 11, the annular flange 113 is integrally formed on the main portion 111 of the fastener 11 and thus cannot drop off from the main portion 111 of the fastener 11. That is, the annular flange 113 and the main portion 111 are monolithically integral.

It is to be understood, however, that even though numerous characteristics and advantages of the embodiments have been set forth in the foregoing description, together with details of the structures and functions of the embodiment(s), the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation module, comprising:
a base comprising a sleeve, the sleeve defining a through aperture, the through aperture comprising a large hole and a small hole having a diameter smaller than the large hole, the sleeve comprising a step where the large hole communicates with the small hole, the sleeve having a through slot defined therein along an axial direction thereof thereby separating the sleeve into two clamping portions spaced from each other; and
a fastener comprising a main portion, a head portion formed at a top end of the main portion, an annular flange extending outwardly from an outer circumferential surface of a bottom end of the main portion, and a coil spring, the coil spring mounted around the main portion, and the annular flange having a diameter greater than that of the small hole;
wherein when the fastener is mounted to the base, the fastener is pushed downwardly into the through aperture, the annular flange is driven to enter the small hole such that the two clamping portions elastically expand outwardly away from each other, and after the annular flange has passed through the small hole, the clamping portions rebound back to their original states and the annular flange abuts against a bottom of the sleeve, with the coil spring located between the head portion of the fastener and the step of the sleeve.

2. The heat dissipation module of claim 1, wherein the fastener further comprises a thread portion at the bottom end of the main portion below the annular flange.

3. The heat dissipation module of claim 1, wherein the coil spring is partly received in the large hole and has an outer diameter greater than that of the small hole of the through aperture of the sleeve.

4. The heat dissipation module of claim 1, wherein the annular flange has an annular filleted surface at a bottom thereof, and the annular filleted surface is configured for guiding the annular flange to move into the small hole of the through aperture.

5. The heat dissipation module of claim 1, further comprising a heat pipe and a fin assembly, wherein one end of the heat pipe is thermally connected with the base, and another end of the heat pipe is thermally connected with the fin assembly.

6. A heat dissipation module, comprising:
a base comprising a sleeve, the sleeve defining a through aperture, the through aperture comprising a large hole and a small hole having a diameter smaller than the large hole, the sleeve comprising a step where the large hole communicates with the small hole, the sleeve having a through slot defined therein along an axial direction thereof thereby separating the sleeve into two clamping portions spaced from each other;
a fin assembly;
a heat pipe, one end of the heat pipe being thermally connected with the base, another end of the heat pipe being thermally connected with the fin assembly; and
a fastener comprising a main portion, a head portion formed at a top end of the main portion, an annular flange extending outwardly from an outer circumferential surface of a bottom end of the main portion, and a coil spring, the coil spring mounted around the main portion, and the annular flange having a diameter greater than that of the small hole; wherein when the fastener is mounted to the base, the fastener is pushed downwardly into the through aperture, the annular flange is driven to enter the small hole such that the two clamping portions elastically expand outwardly away from each other, and after the annular flange has passed through the small hole, the clamping portions rebound back to their original states and the annular flange abuts against a bottom of the sleeve, with the coil spring located between the head portion of the fastener and the step of the sleeve.

7. The heat dissipation module of claim 6, wherein the fastener further comprises a thread portion at the bottom end of the main portion below the annular flange.

8. The heat dissipation module of claim 6, wherein the coil spring is partly received in the large hole and has an outer diameter greater than that of the small hole of the through aperture of the sleeve.

9. The heat dissipation module of claim 6, wherein the annular flange has an annular filleted surface at a bottom thereof, and the annular filleted surface is configured for guiding the annular flange to move into the small hole of the through aperture.
